(19) United States
(12) Patent Application Publication
(10) Pub. No.: US 2017/0309457 A1
(43) Pub. Date: Oct. 26, 2017

(54) SUBSTRATE PROCESSING APPARATUS

(71) Applicant: ASM IP Holding B.V., Almere (NL)

(72) Inventor: Kazunori FURUKAWAHARA, Nagaoka-shi (JP)

(73) Assignee: ASM IP Holding B.V., Almere (NL)

(21) Appl. No.: 15/139,174

(22) Filed: Apr. 26, 2016

(51) Int. Cl. H01J 37/32; F16K 43/00; H01L 21/67

(52) U.S. Cl. CPC H01J 37/32513; H01L 21/67069; H01J 37/32899; H01J 37/32082; F16K 43/001; H01J 37/32807; H01J 2237/332; H01J 2237/334

(57) ABSTRACT

A substrate processing apparatus includes a chamber in which a first processing space, a second processing space, a connecting space connecting the first processing space and the second processing space, a first hole connecting with the connecting space and a second hole connecting with the connecting space are formed, a first gate valve having a first valve element and closing the first hole, the first valve element sliding in the first hole, opening and closing the connecting space, and a second gate valve having a second valve element and closing the second hole, the second valve element sliding in the second hole, opening and closing the connecting space, wherein a region in which the first hole and the connecting space connect with each other and a region in which the second hole and the connecting space connect with each other are one common region.

### BACKGROUND OF THE INVENTION

### Field of the Invention

The present invention relates to a substrate processing apparatus used, for example, to transport substrates.

### Background Art

JP 6-185634 A discloses a valve element provided between a vacuum processing chamber and a transport chamber.

A gate valve is fixed in a chamber to connect a plurality of spaces in the chamber or shut off the spaces from each other. There is a need for regular maintenance on the gate valve for replacing a sealing member such as an O-ring fixed on the gate valve and for correcting a malfunctioning condition of the gate valve. When such maintenance is performed, the gate valve is removed from the chamber, so that the chamber is exposed to the atmosphere and a need arises to stop processing with the entire system.

An arrangement for solving these problems is conceivable in which a plurality of gate valves are disposed between two chambers. In such a case, when one gate valve is removed, the path between the chambers is closed by another gate valve, thus enabling solution of the above-described problems. In the case where a plurality of gate valves are disposed, however, the area occupied by the apparatus is correspondingly increased.

### SUMMARY OF THE INVENTION

In view of the above-described problems, an object of the present invention is to provide a substrate processing apparatus capable of preventing exposure of a chamber to the atmosphere or interruption of processing without increasing the area occupied by the apparatus.

The features and advantages of the present invention may be summarized as follows.

According to one aspect of the present invention, a substrate processing apparatus includes a chamber in which a first processing space, a second processing space, a connecting space connecting the first processing space and the second processing space, a first hole connecting with the connecting space and a second hole connecting with the connecting space are formed, a first gate valve having a first valve element and closing the first hole, the first valve element sliding in the first hole, opening the connecting space and closing the connecting space, and a second gate valve having a second valve element and closing the second hole, the second valve element sliding in the second hole, opening the connecting space and closing the connecting space, wherein a region in which the first hole and the connecting space connect with each other and a region in which the second hole and the connecting space connect with each other are one common region.

Other and further objects, features and advantages of the invention will appear more fully from the following description.

### BRIEF DESCRIPTION OF THE DRAWINGS

FIG. 1 is a sectional view of a substrate processing apparatus according to a first embodiment;

FIG. 2 is a diagram showing a state where the connecting spaces are closed;

FIG. 3 is a sectional view of a substrate processing apparatus according to the comparative example;

FIG. 4 is a plan view of the substrate processing apparatuses;

FIG. 5 is a diagram showing a substrate processing apparatus according to a modified example;

FIG. 6 is a sectional view of the substrate processing apparatus according to the second embodiment;

FIG. 7 is a diagram showing the substrate processing apparatus at the time of maintenance;

FIG. 8 shows an enlarged view of the second valve element;

FIG. 9 is a diagram showing a modified example of the second valve element;

FIG. 10 is a diagram showing the substrate processing apparatus according to the third embodiment;

FIG. 11 is a diagram showing a state where processing is performed on substrates in the RC;

FIG. 12 is a diagram showing the substrate processing apparatus according to the fourth embodiment; and

FIG. 13 is a sectional view taken along broken line in FIG. 12.

### DETAILED DESCRIPTION OF THE PREFERRED EMBODIMENTS

A substrate processing apparatus according to an embodiment of the present invention will be described with reference to the drawings. Components identical or corresponding to each other are assigned the same reference characters, and repeated description of them is omitted in some cases.

### First Embodiment

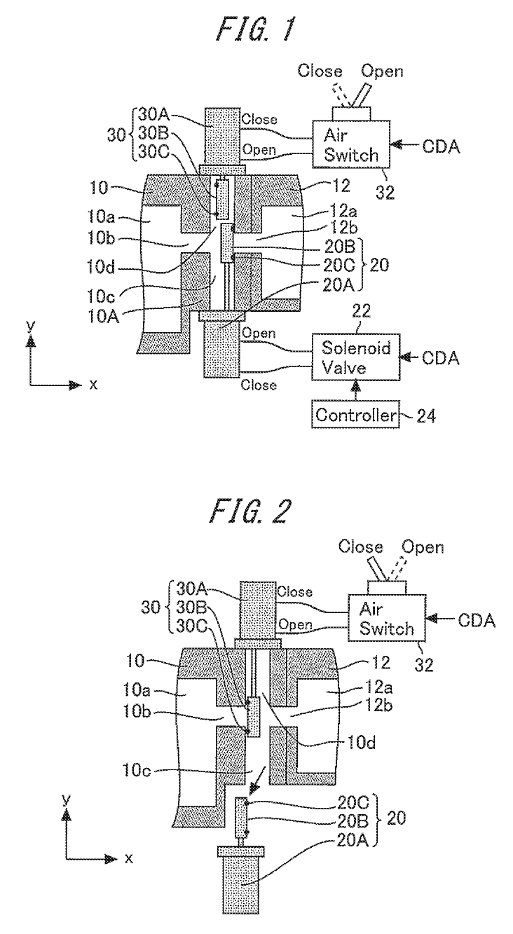

FIG. 1 is a sectional view of a substrate processing apparatus according to a first embodiment of the present invention. The substrate processing apparatus is provided with a wafer handling chamber (WHC) 10 and a reactor chamber (RC) 12. A first processing space 10a is formed in the WHC 10. The first processing space 10a is a space secured for transport of substrates. Therefore, a robot arm for transporting substrates is housed in the first processing space 10a.

A second processing space 12a is formed in the RC 12. The second processing space 12a is a space secured for performing processing such as film forming or etching on substrates. Therefore, components including a susceptor on which substrates are placed and an RF plate for generation of plasma are provided in the second processing space 12a. Vacuum pumps are connected to the WHC 10 and the RC 12 in order to evacuate the first processing space 10a and the second processing space 12a.

Connecting spaces 10b and 12b for connecting the first processing space 10a and the second processing space 12a are formed in the WHC 10 and the RC 12. The connecting space 10b is formed in the WHC 10 while the connecting space 12b is formed in the RC 12. Each of the connecting spaces 10b and 12b is a space extending along the x-direction.

A first hole 10c connecting with the connecting space 10b and a second hole 10d connecting with the connecting space 10b are formed in the WHC 10. The first hole 10c is a hole formed on a lower surface of the WHC 10 and extending in the y positive direction. The second hole 10d is a hole formed on an upper surface of the WHC 10 and extending in the y negative direction. The first hole 10c and the second hole 10d extend along the y-direction and the connecting spaces 10b and 12b extend along the x-direction. Accordingly, the first hole 10c and the second hole 10d intersect the connecting spaces 10b and 12b.

A portion 10A of the WHC 10 is a portion connected to the RC 12. The first hole 10c, the second hole 10d and the connecting space 10b are formed in the portion 10A.

A first gate valve 20 is fixed on the lower surface of the portion 10A of the WHC 10. The first hole 10c is closed by the first gate valve 20. The first gate valve 20 is screw-fastened to the WHC 10 while suitably squeezing an O-ring provided therebetween. The first gate valve 20 is thereby fixed on the WHC 10. A fixing method different from this may be used. The first gate valve 20 has a first body 20A, a first valve element 20B and an O-ring 20C fixed on the first valve element 20B. A cylinder and a piston reciprocatingly movable in the cylinder are provided in the first body 20A. The first valve element 20B moves interlockingly with this piston.

A solenoid valve 22 is connected to the first gate valve 20. A controller 24 is connected to the solenoid valve 22. Compressed dry air (CDA) is supplied from the outside to the solenoid valve 22. The solenoid valve 22 supplies CDA to an opening side or a closing side of the first body 20A according to a signal received from the controller 24. When CDA is supplied to the opening side, the first valve element 20B withdraws into the first hole 10c so that the connecting spaces 10b and 12b connect with each other. When CDA is supplied to the closing side, the first valve element 20B enters the connecting space 10b to close the connecting spaces 10b and 12b. More specifically, the first valve element 20B first moves in the y positive direction and thereafter moves in the x positive direction. Thus, the first valve element 20B slides in the first hole 10c and opens or closes the connecting spaces 10b and 12b.

A second gate valve 30 is fixed on the upper surface of the portion 10A of the WHC 10. The second hole 10d is closed by the second gate valve 30. The second gate valve 30 is screw-fastened to the WHC 10 while suitably squeezing an O-ring provided therebetween. The second gate valve 30 is thereby fixed on the WHC 10. A fixing method different from this may be used. The second gate valve 30 has a second body 30A, a second valve element 30B and an O-ring 30C fixed on the second valve element 30B. A cylinder and a piston reciprocatingly movable in the cylinder are provided in the second body 30A. The second valve element 30B moves interlockingly with this piston.

A manual switching device 32 is connected to the second gate valve 30. The manual switching device 32 has a lever manually operated to select whether to supply CDA to an opening side of the second gate valve 30 or to a closing side of the second gate valve 30. When CDA is supplied to the opening side, the second valve element 30B withdraws into the second hole 10d so that the connecting spaces 10b and 12b connect with each other. When CDA is supplied to the closing side, the second valve element 30B enters the connecting space 10b to close the connecting spaces 10b and 12b. More specifically, the second valve element 30B first moves in the y negative direction and thereafter moves in the x negative direction. Thus, the second valve element 30B slides in the second hole 10d and opens or closes the connecting spaces 10b and 12b.

The operation of the substrate processing apparatus according to the first embodiment of the present invention will be described. When substrates are processed with the substrate processing apparatus, the manual switching device 32 is set at a closing side at all times to maintain the second valve element 30B in the state of being withdrawn in the second hole 10d. Opening/closing of the first gate valve 20 when substrates are processed with the substrate processing apparatus is controlled by the controller 24 issuing the signal to the solenoid valve 22 on the basis of a recipe.

More specifically, when substrates are moved from the first processing space 10a into the second processing space 12a, or when substrates are moved from the second processing space 12a into the first processing space 10a, the controller 24 issues the signal to the solenoid valve 22 to supply CDA to the opening side of the first gate valve 20. The first valve element 20B is thereby withdrawn into the first hole 10c. When processing such as film forming or etching is performed on substrates in the second processing space 12a, the controller 24 issues the signal to the solenoid valve 22 to supply CDA to the closing side of the first gate valve 20. The first valve element 20B is thereby caused to close the connecting spaces 10b and 12b.

More specifically, the first valve element 20B is moved in the y positive direction and is thereafter moved in the x positive direction, thereby pressing the O-ring 20C on the RC 12 side of the WHC 10. The first gate valve 20 thus shuts off the second processing space 12a from the first hole 10e and the second hole 10d when closing the connecting spaces 10b and 12b. In the state where the RC 12 is enclosed with the first gate valve 20 in the above-described way, processing is performed on substrates in the second processing space 12a.

At the time of maintenance on the substrate processing apparatus, substrate processing such as film forming or etching in the second processing space 12a is stopped. CDA is then supplied to the opening side of the first gate valve 20 to withdraw the first gate valve 20 into the first hole 10c. The lever of the manual switching device 32 is thereafter turned to the closing side to close the connecting spaces 10b and 10c with the second gate valve 30. FIG. 2 is a diagram showing a state where the connecting spaces 10b and 12b are closed with the second gate valve 30. When the connecting spaces 10b and 12b are to be closed with the second gate valve 30, the second valve element 30B is moved in the y negative direction and is thereafter moved in the x negative direction, thereby pressing the O-ring 30C against the surface on the WHC 10 side. The second gate valve 30 thus shuts off the first processing space 10a from the first hole 10c and the second hole 10d when closing the connecting spaces 10b and 12b.

After securing the enclosure of the first processing space 10a in the above-described way, the first gate valve 20 is removed from the WHC 10 and a predetermined maintenance operation is performed. The maintenance operation is, for example, replacement of the O-ring 20C or the first valve element 20B including the O-ring 20C. The O-ring 20C is easily damaged, for example, if it is exposed to a processing atmosphere including oxygen radicals in the RC 12. In such a case, the main objective of maintenance is to replace the O-ring 20C.

At the time of maintenance, the first processing space 10a is not exposed to the atmosphere since the first processing space 10a is enclosed with the second gate valve 30. Substrate processing in the first processing space 10a can therefore be continued during maintenance. For example, in a case where an RC different from the RC 12 is connected to the WHC, delivery of substrates between the different RC and the WHC can be continued.

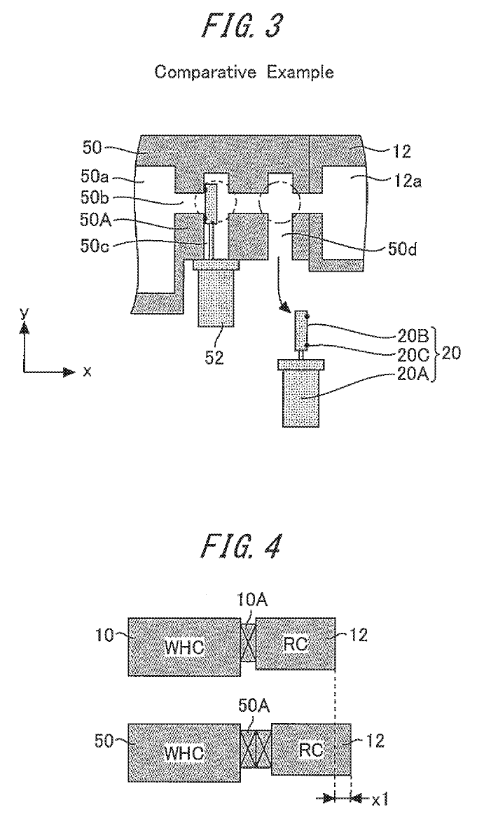

A comparative example will be described to facilitate understanding of the technical significance of the substrate processing apparatus according to the first embodiment of the present invention. FIG. 3 is a sectional view of a substrate processing apparatus according to the comparative example. The substrate processing apparatus according to the comparative example is provided with a WHC 50 in which a first processing space 50a is formed. In a portion 50A of the WHC 50 connected to the RC 12, a first hole 50c and a second hole 50d are formed by being laterally placed side by side. Therefore, the length in the x-direction of the connecting space 50b is larger than the length in the x-direction of the connecting spaces 10b and 12b shown in FIG. 1.

A region in which the first hole 50c and the connecting space 50b connect with each other, and which is indicated by a broken-line circle in FIG. 3, and a region in which the second hole 50d and the connecting space 50b connect with each other, and which is indicated by a dot-dash-line circle, exist separately from each other. When substrates are processed in the second processing space 12a, the second processing space 12a is enclosed with the first gate valve 20. On the other hand, at the time of maintenance, the first processing space 50a in the WHC 50 is closed with the second gate valve 52, thereby enabling transport of substrates in the WHC 50 to be continued during maintenance. In the substrate processing apparatus in the comparative example, however, there is a need to form the portion 50A of the WHC 50 so that the length of the portion 50A in the x-direction is large, since the first hole 50c and the second hole 50d are formed by being laterally placed side by side. Therefore, the comparative example has a problem that the apparatus is increased in size.

In the substrate processing apparatus according to the first embodiment of the present invention, the region in which the first hole 10c and the connecting space 10b connect with each other and the region in which the second hole 10d and the connecting space 10b connect with each other are one common region. In other words, the first gate valve 20 and the second gate valve 30 are provided on a vertical plane perpendicular to the direction in which substrates are moved when delivery of substrates between the WHC 10 and the RC 12 is performed. Even in comparison with a case where only the first gate valve 20 is provided and the second gate valve 30 is not provided, therefore, the area occupied by the apparatus does not increase as a result of the provision of both the first and second gate valves 20 and 30.

FIG. 4 is a plan view of the substrate processing apparatus according to the first embodiment of the present invention and the substrate processing apparatus according to the comparative example. In the comparative example, the portion 50A connecting the WHC 50 and the RC 12 is large since the two gate valves are laterally placed side by side. On the other hand, in the first embodiment of the present invention, the area occupied by the apparatus does not increase as a result of addition of the second gate valve 30. Thus, the substrate processing apparatus according to the first embodiment of the present invention is capable of continuing substrate processing in the WHC 10 even during maintenance while the area occupied by the apparatus is not increased.

If the direction in which the first gate valve 20 slides and the direction in which the second gate valve 30 slides are aligned with one straight line in the vertical direction (y-direction), the increase in the area occupied by the apparatus due to the provision of the first and second gate valves 20 and 30 can be limited to the least possible value. That is, the width of the portion 10A can be minimized.

In the first embodiment of the present invention, the WHC 10 in which the first processing space 10a, the connecting space 10b, the first hole 10c and the second hole 10d are formed and the RC 12 in which the connecting space 12b and the second processing space 12a are formed are adopted as chambers. In various arrangements having gate valves provided between two processing spaces not limited to the WHC 10 and the RC 12, however, the first and second gate valves 20 and 30 can be incorporated. The first and second gate valves according to the first embodiment may be incorporated, for example, between a load lock chamber and an equipment front end module (EFEM).

In any case, achieving the effects of the present invention requires forming in a chamber a first processing space, a second processing space, a connecting space connecting the first processing space and the second processing space, a first hole connecting with the connecting space and a second hole connecting with the connecting space. The chamber may be one component part or may be constituted of a plurality of component parts, as described with respect to the first embodiment. A member called a housing may be provided between the chamber in which the first processing space is formed and the chamber in which the second processing space is formed to connect the chambers with each other. In such a case, the first hole and the second hole are formed in the housing and the first gate valve and the second gate valve are attached to the housing.

Any of well-known mechanisms can be adopted as the mechanism of the first and second gate valves 20 and 30. A control means different from that shown in Fig, 1 may be adopted if it is capable of opening and closing the first gate valve 20 on the basis of a recipe, and if the second gate valve 30 can be manually opened and closed. For example, an arrangement for controlling opening/closing of the second gate valve 30 with buttons may be adopted.

In the above-described arrangement, the O-ring 20C is fixed on the first valve element 20B and the O-ring 30C is fixed on the second valve element 30B. However, a component part different from the O-ring may alternatively be used. In terms of superordinate concept, a first rubber and a second rubber may be fixed on the first valve element 20B and the second valve element 30B, respectively. The first and second rubbers are used for enclosure of the processing spaces. For example, the first and second rubbers may be baked on the first and second valve elements. Control of the second gate valve 30 with the controller is not preferable because it complicates the control process.

The first gate valve 20 is fixed on the lower surface of the WHC 10, and the second gate valve 30 is fixed on the upper surface of the WHC 10. These valves, however, may be fixed at different positions. For example, the first gate valve 20 may be fixed on one side surface of the WHC 10, and the second gate valve 30 on another side surface of the WHC 10.

FIG. 5 is a diagram showing a substrate processing apparatus according to a modified example. A second gate valve 34 has a second body 34A, a second valve element 34B and an O-ring 34C. The second gate valve 34 shuts off the second processing space 12a from the first hole 10c and the second hole 10d when closing the connecting spaces 10b and 12b. That is, the O-ring 34C is pressed on the RC 12 side to enclose the second processing space 12a. Exposure of the second processing space 12a in the RC 12 to the atmosphere at the time of maintenance and, hence, contamination in the second processing space 12a can thus be prevented.

Needless to say, objects to be processed with the substrate processing apparatus are not limited to wafers. Substrates to be processed in semiconductor processes or the like are included in a variety of objects which can be processed with the substrate processing apparatus. The WHC 10 is an example of implementation of a substrate handling chamber.

These modifications can be applied as desired to substrate processing apparatuses according to embodiments described below. Each of the substrate processing apparatuses according to embodiments described below has a number of commonalities with the first embodiment and will therefore be described mainly with respect to points of difference from the first embodiment.

### Second Embodiment

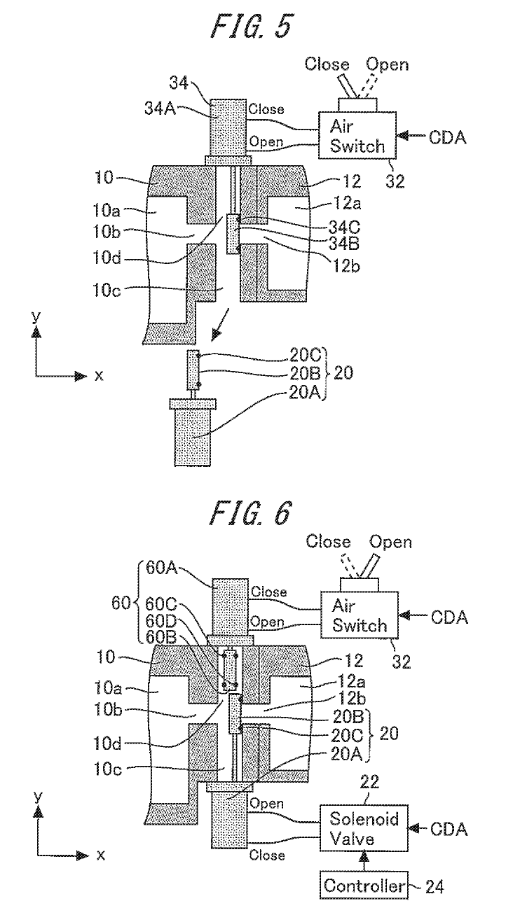

FIG. 6 is a sectional view of the substrate processing apparatus according to the second embodiment. A second gate valve 60 has a second body 60A, a second valve element 60B, an O-ring 60C fixed on the first processing space 10a side of the second valve element 60B, and an O-ring GOD fixed on the second processing space 12a side of the second valve element 60B. FIG. 6 shows a state where the second processing space 12a is enclosed with the first gate valve 20 when substrates are processed in the RC 12.

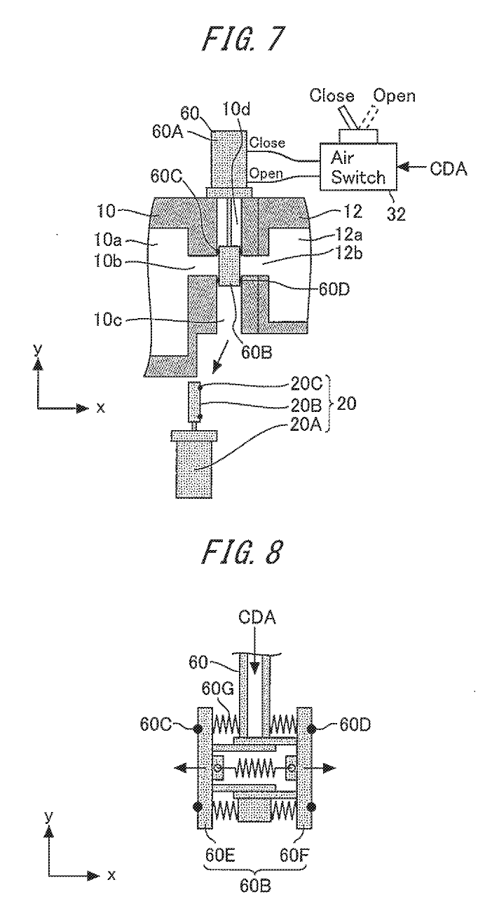

FIG. 7 is a diagram showing the substrate processing apparatus at the time of maintenance. At the time of maintenance, the connecting spaces 10b and 12b are closed with the second valve element 60B. The width of the second valve element 60B is made larger at this time than when the connecting spaces 10b and 12b are opened, thereby shutting off the first processing space 10a and the second processing space 12a from the first hole 10c and the second hole 10d. That is, the O-ring 60C is brought into contact with the wall on the first processing space 10a side and the O-ring 60D is brought into contact with the wall on the second processing space 12a side, thereby enclosing the first processing space 10a and the second processing space 12a.

FIG. 8 shows an enlarged view of the second valve element 6013. At the time of maintenance, the width of the second valve element 60B can be increased by supplying CDA to the second valve element 60B. More specifically, the O-ring 60C is fixed on a plate 60E which is moved in the x negative direction by supplying CDA, and the O-ring 60D is fixed on a plate 60F which is moved in the x positive direction by supplying CDA, thereby enabling enclosing the first processing space 10a and the second processing space 12a at the time of maintenance. When supply of CDA is stopped, springs 60G contract to bring the plates 60E and 60F closer to each other, thereby reducing the width of the second valve element 60B.

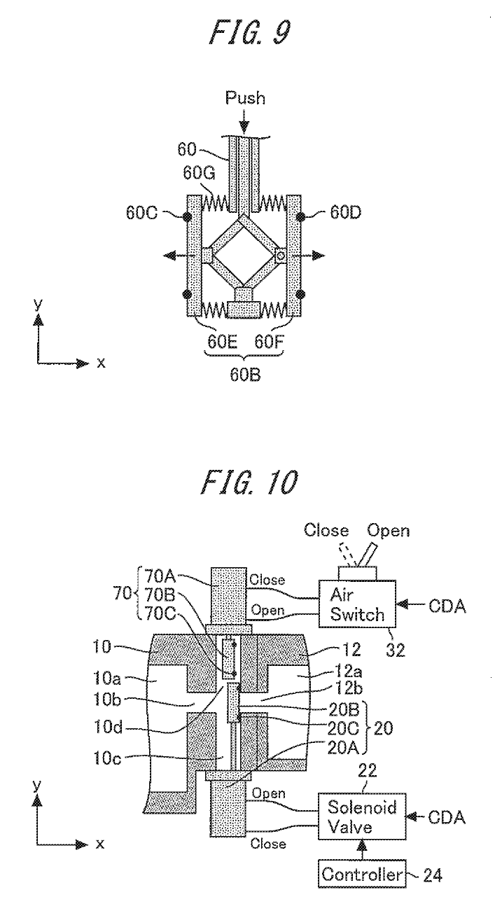

FIG. 9 is a diagram showing a modified example of the second valve element. FIG. 9 shows increase of the width of the second valve element 60B caused by exerting force in the y negative direction on the second valve element 60B. The second valve element is thus changed in width by air supplied to the second valve element or by a force exerted on the second valve element. A construction of the second valve element other than those shown in FIGS. 8 and 9 may alternatively be adopted.

In an ultrahigh vacuum platform, if the WHC or the RC is exposed to the atmosphere at the time of maintenance, moisture or the like is adsorbed in the WHC or the RC and an extremely long time is taken to restore an ultrahigh vacuum or a need arises for baking of the apparatus. Maintaining a vacuum in both the WHC 10 and the RC 12 by using the second gate valve 60 according to the second embodiment is particularly effective in coping with such a problem.

### Third Embodiment

FIG. 10 is a diagram showing the substrate processing apparatus according to the third embodiment. The first gate valve 20 and a second gate valve 70 have structures identical to each other. That is, the first gate valve 20 and the second gate valve 70 are of the same design. More specifically, the first body 20A and a second body 70A are identical in structure to each other; the first valve element 20B and a second valve element 70B are identical in structure to each other; and the O-ring 20C and an O-ring 70C are identical in structure to each other.

When the first gate valve 20 is closed, and when the second gate valve 70 is closed, the second processing space 12a is shut off from the first hole 10c and the second hole 10d. When substrates are processed with the substrate processing apparatus, the first gate valve 20 is opened and closed in the same way as that described above with respect to the first embodiment. At the time of maintenance, the handle of the manual switching device 32 is turned to the closing side to shut off the connecting spaces 10b and 12b with the second gate valve 70.

In a case where a malfunction occurs in the first gate valve 20 and the first gate valve 20 cannot be normally operated, processing on substrates can be continued by using the second gate valve 70 in place of the first gate valve 20. FIG. 11 is a diagram showing a state where processing is performed on substrates in the RC 12 while the second gate valve 70 is closed. When the second gate valve 70 is used in place of the first gate valve 20, the connection of the solenoid valve 22 and the controller 24 is changed to the second gate valve 70. The second gate valve 70 is opened and closed on the basis of a recipe. At the time of maintenance, the first gate valve 20 is removed from the WHC 10 while the second processing space 12a is closed with the second gate valve 70.

Making the first gate valve 20 and the second gate valve 70 identical in structure to each other thus enables control of the opening/closing of only one of the first gate valve 20 and the second gate valve 70 with the controller 24 on the basis of a recipe.

### Fourth Embodiment

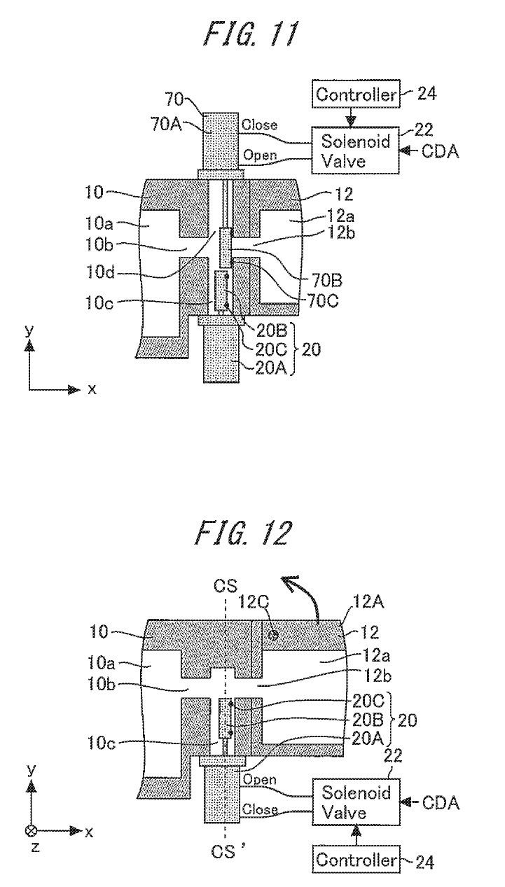

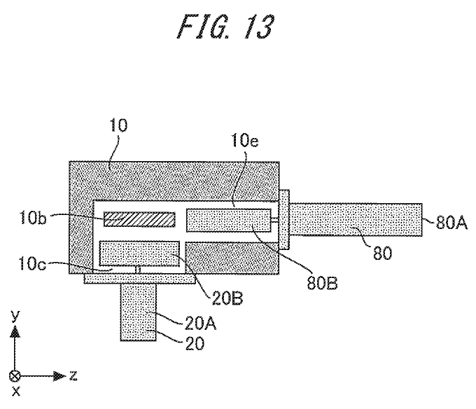

FIG. 12 is a diagram showing the substrate processing apparatus according to the fourth embodiment. The first gate valve 20 is attached to the lower surface of the WHC 10. No gate valve is attached to the upper surface of the WHC 10. An upper lid 12A of the RC 12 is movable in the direction of the arrow on a shaft 12c. FIG. 13 is a sectional view taken along broken line CS-CS′ in FIG. 12. A hole 10e extending laterally and connecting with the connecting space 10b is formed in a side surface of the WHC 10. The hole 10e is closed with a second gate valve 80 attached to the side surface of the WHC 10. A second body 80A of the second gate valve 80 is fixed on the side surface of the WHC 10. The second valve element 80B is moved mainly in the z positive and z negative directions in the hole 10e to open and close the connecting space 10b. The operation of the substrate processing apparatus according to the fourth embodiment is essentially the same as that of the apparatus according to the first embodiment.

In the first embodiment, as shown in FIG. 1, the second gate valve 30 is provided right above the first gate valve 20. In this arrangement, however, there is a possibility of an overlap between the region through which the upper lid of the RC 12 can move and the set position of the second gate valve 30.

In the fourth embodiment, therefore, the second gate valve 80 is attached to the side surface of the WHC 10 to enable opening/closing of the upper lid 12A of the RC 12 while the second gate valve 80 is provided. Thus, the area occupied by the apparatus is not increased when a plurality of gate valves are provided on a flat plane intersecting the connecting spaces 10b and 12b.

Therefore, the first gate valve 20 shown in FIG. 1, the second gate valve 30 shown in FIG. 1 and the second gate valve 34 shown in FIG. 5 may be provided on a flat plane intersecting the connecting spaces 10b and 12b. When the second gate valve 30 is attached to the upper surface of the WHC 10, the second gate valve 34 is attached to the side surface of the WHC 10. When the second gate valve 34 is attached to the upper surface of the WHC 10, the second gate valve 30 is attached to the side surface of the WHC 10.

A suitable combination of the features of the substrate processing apparatus according to the embodiments described above may be made and used.

According to the present invention, a plurality gate valves are provided in a vertical direction, thereby enabling prevention of exposure of the chamber to the atmosphere or interruption of processing without increasing the area occupied by the apparatus.

Obviously many modifications and variations of the present invention are possible in the light of the above teachings. It is therefore to be understood that within the scope of the appended claims the invention may be practiced otherwise than as specifically described.

What is claimed is:

1. A substrate processing apparatus comprising:
a chamber in which a first processing space, a second processing space, a connecting space connecting the first processing space and the second processing space, a first hole connecting with the connecting space and a second hole connecting with the connecting space are formed;
a first gate valve having a first valve element and closing the first hole, the first valve element sliding in the first hole, opening the connecting space and closing the connecting space; and
a second gate valve having a second valve element and closing the second hole, the second valve element sliding in the second hole, opening the connecting space and closing the connecting space,
wherein a region in which the first hole and the connecting space connect with each other and a region in which the second hole and the connecting space connect with each other are one common region.

2. The substrate processing apparatus according to claim 1, further comprising:
a controller which controls opening and closing of the first gate valve on the basis of a recipe; and
a manual switching device which selects between opening and closing of the second gate valve.

3. The substrate processing apparatus according to claim 1, wherein the chamber includes:
a substrate handling chamber in which the first processing space, the connecting space, the first hole and the second hole are formed; and
a reactor chamber in which the connecting space and the second processing space are formed.

4. The substrate processing apparatus according to claim 3, wherein the first gate valve shuts off the second processing space from the first hole and the second hole when closing the connecting space, and
wherein the second gate valve shuts off the first processing space from the first hole and the second hole when closing the connecting space.

5. The substrate processing apparatus according to claim 3, wherein the first gate valve shuts off the second processing space from the first hole and the second hole when closing the connecting space, and
wherein the second gate valve shuts off the second processing space from the first hole and the second hole when closing the connecting space.

6. The substrate processing apparatus according to claim 1, wherein a direction in which the first gate valve slides and a direction in which the second gate valve slides are aligned with one straight line.

7. The substrate processing apparatus according to claim 1, further comprising a first rubber fixed on the first valve element and a second rubber fixed on the second valve element.

8. The substrate processing apparatus according to claim 1, wherein the second gate valve is provided right above the first gate valve.

9. The substrate processing apparatus according to claim 1, wherein the first gate valve is attached to a lower surface of the chamber, and the second gate valve is attached to a side surface of the chamber.

10. The substrate processing apparatus according to claim 1, wherein the second valve element is made larger in width when closing the connecting space than when opening the connecting space to shut off the first processing space and the second processing space from the first hole and the second hole.

11. The substrate processing apparatus according to claim 10, wherein the second valve element is constructed so as to be changed in width by air supplied to the second valve element or by a force exerted on the second valve element.

12. The substrate processing apparatus according to claim 1, wherein the first gate valve and the second gate valve have structures identical to each other.

13. The substrate processing apparatus according to claim 12, further comprising a controller which controls the opening/closing of only one of the first gate valve and the second gate valve on the basis of a recipe.
